(19) United States
(12) Patent Application Publication
(10) Pub. No.: US 2008/0029860 A1
(43) Pub. Date: Feb. 7, 2008

(54) SEMICONDUCTOR DEVICE WITH INTERNAL HEAT SINK

(75) Inventor: Wei GAO, Tianjin (CN)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: FREESCALE SEMICONDUCTOR, INC., Austin, TX (US)

(21) Appl. No.: 11/829,084

(22) Filed: Jul. 27, 2007

(30) Foreign Application Priority Data
Aug. 3, 2006 (CN) 200610109096.0

(51) Int. Cl. H01L 23/495

(52) U.S. Cl. 257/675; 257/E23.051

(57) ABSTRACT

A single gauge lead frame for a semiconductor device includes a central die pad surrounded by lead fingers. A heat spreader is attached to a top surface of the die pad. The die pad and the lead fingers have the same thickness. A semiconductor integrated circuit is attached to the heat spreader. After encapsulation, a bottom surface of the heat spreader and the lead fingers is exposed.

### BACKGROUND OF THE INVENTION

The present invention relates to packaged integrated circuits and, more particularly, to a packaged integrated circuit having a heat sink.

Integrated circuits (IC) often are packaged by electrically connecting bonding pads of the IC to lead fingers of a lead frame and encapsulating the die and part of the lead fingers with a plastic mold compound. For high power devices, the lead frame includes a thick die paddle on which the die is supported. The die paddle acts as a heat sink to facilitate heat dissipation.

Referring to FIG. 1, a cross-section of power electronic package 100 is shown. The package 100 includes an IC 102, which is a high power circuit that generates a lot of heat in operation. The IC 102 is attached to a thick die paddle 104. The thick die paddle 104 acts as a heat sink to draw heat away from the IC 102. The IC 102 is electrically connected to lead fingers 106 via wires 108. The IC 102 and portions of the die paddle 104 and lead fingers 106 are covered with a plastic mold compound 110. The die paddle 104 and the lead fingers 106 comprise a lead frame, which is usually formed from a sheet or strip of metal. In this case, the lead frame is a dual gauge lead frame because the die paddle 104 and the lead fingers 106 have different thicknesses (e.g., 20 mils for the die paddle 104 versus 8 mils for the lead fingers 106).

While for high power packages the dual gauge lead frame has some advantages over a single gauge lead frame (in which the die paddle and the lead fingers have the same thickness), such as it is easier to perform singulation, other difficulties may be encountered, such as resin bleed during molding. Thus, it would be desirable to package a power IC with a standard size or thin, single gauge lead frame.

### BRIEF DESCRIPTION OF THE DRAWINGS

The following detailed description of a preferred embodiment of the invention will be better understood when read in conjunction with the appended drawings. For the purpose of illustrating the invention, there is shown in the drawings an embodiment that is presently preferred. It should be understood, however, that the invention is not limited to the precise arrangement and instrumentalities shown. In the drawings:

FIG. 1 is an enlarged cross-sectional view of a prior art packaged semiconductor device;

FIG. 2 is an enlarged cross-sectional view of a packaged semiconductor device in accordance with an embodiment of the present invention; and

FIG. 3 is a flow chart of a method of forming the packaged device of FIG. 2.

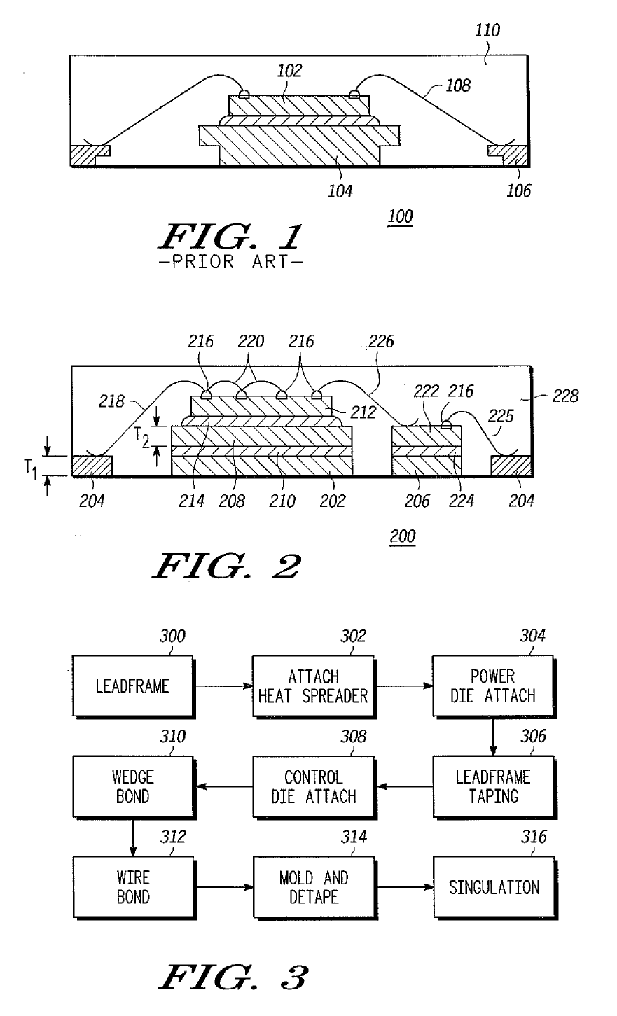

### DETAILED DESCRIPTION OF PREFERRED EMBODIMENT

The detailed description set forth below in connection with the appended drawings is intended as a description of the presently preferred embodiment of the invention, and is not intended to represent the only form in which the present invention may be practiced. It is to be understood that the same or equivalent functions may be accomplished by different embodiments that are intended to be encompassed within the spirit and scope of the invention. As will be understood by those of skill in the art, the present invention can be applied to various packages and package types.

Certain features in the drawings have been enlarged for ease of illustration and the drawings and the elements thereof are not necessarily in proper proportion. Further, the invention is shown embodied in a Quad Flat No-lead (QFN) type package. However, those of ordinary skill in the art will readily understand the details of the invention and that the invention is applicable to other package types. In the drawings, like numerals are used to indicate like elements throughout.

In one embodiment, the present invention is a single gauge lead frame for a semiconductor device, including a central die pad and a plurality of lead fingers surrounding the die pad. The die pad and the lead fingers have a first thickness, such as 8 mils, which is a relatively common thickness dimension used in semiconductor packaging. A heat spreader having a second thickness is attached to a first surface of the die pad, wherein a semiconductor integrated circuit will be attached to a second surface of the heat spreader.

In another embodiment, the present invention further provides a semiconductor device including a die pad and a plurality of lead fingers surrounding the die pad. The die pad and the lead fingers have a first thickness. A heat spreader having a second thickness is attached to a first surface of the die pad. An integrated circuit (IC) is attached to a second surface of the heat spreader. A plurality of wires electrically connects respective ones of the plurality of lead fingers to respective bonding pads on the integrated circuit. A mold compound surrounds the integrated circuit, the plurality of wires, and a top surface of the lead fingers, wherein a second surface of the die pad is exposed to facilitate dissipation of heat generated by the IC during operation thereof.

In another embodiment, the present semiconductor device includes a second IC, such as a control IC, disposed on a second die pad located adjacent to the first die pad, and also electrically connected to one or more of the lead fingers.

In yet a further embodiment, the present invention provides a method of packaging a semiconductor device, including the steps of:

providing a lead frame having a central die pad and a plurality of lead fingers surrounding the die pad and extending inwardly toward the die pad, wherein the die pad and the lead fingers have substantially the same thickness and are formed from a single sheet of metal;

attaching a first surface of a heat sink to a first surface of the die pad;

attaching a semiconductor integrated circuit to a second surface of the heat sink;

electrically connecting bonding pads of the semiconductor integrated circuit with respective ones of the lead fingers with a plurality of wires; and

forming a mold compound over the semiconductor integrated circuit, the wires, the heat sink, and at least a portion of the die pad and lead fingers, wherein a second surface of the die pad is exposed.

Referring now to FIG. 2, an enlarged cross-sectional view of an embodiment of a semiconductor device 200 in accordance with the present invention is shown. The semiconductor device 200 is formed using a single gauge type lead frame. The single gauge lead frame includes at least a first die pad 202 and a plurality of lead fingers 204 that surround the first die pad 202 and extend inwardly toward the first die pad 202. In one embodiment, the lead frame includes a second die pad 206, which is located adjacent to the first die pad 202 and also is surrounded by the lead fingers 204. The lead frame may be formed from metal or metal alloy. In one embodiment, the lead frame is formed from a single sheet of metal, such as copper, with the first and second die pads 202 and 206 and the lead fingers 204 being formed via cutting, stamping or etching, as is known by those of skill in the art. As the first and second die pads 202 and 206 and the lead fingers 204 are formed from a single metal sheet, the first and second die pads 202 and 206 and the lead fingers 204 all have the same thickness, denoted as T₁ in FIG. 2. In one embodiment of the invention, the thickness T₁ is about 8 mils, which is a relatively common size and hence, the lead frame may be readily obtained at a low cost. Further, a lead frame having a thickness of about 8 mils is easily cut or singulated.

A heat spreader 208 is attached to a first or top surface of the first die pad 202. More particularly, a first or bottom surface of the heat spreader 208 is attached to the first or top surface of the first die pad 202. The heat spreader 208 is formed of a material have good thermal conductivity, like copper, and may be formed by cutting, stamping or etching a copper sheet. As is understood by those of skill in the art, the first and second die pads 202 and 206, the lead fingers 204, and the heat sink 208 may be plated with a metal or metal alloy, such as NiPd.

The heat spreader 208 can be smaller or larger (length, width, thickness) than the first die pad 202. However, as shown in FIG. 2, the heat spreader 208 also may have generally the same length and width as the first die pad 202. The heat spreader 208 has a second thickness, denoted as T₂. The second thickness T₂ may be greater than or less than the first thickness T₁. For example, in one embodiment, the second thickness T₂ is substantially equal to the first thickness T₁, while in another embodiment, for example, for power circuits that generate a lot of heat, in order to increase heat dissipation yet not increase the first thickness T₁, the second thickness T₂ is greater than the first thickness T₁ (e.g., T₁=8 mils and T₂=12 mils). The heat spreader 208 may be attached to the die pad 202 using an epoxy or an adhesive tape. However, in order to increase heat transfer, in one embodiment of the invention, the heat spreader 208 is attached to the first die pad 202 with a high temperature solder 210.

An integrated circuit die 212 is attached to a second or top surface of the heat sink 208. The integrated circuit die 212 may be of a type known to those of skill in the art, such as a circuit formed on and cut from a silicon wafer, and in one embodiment, the integrated circuit die 212 is a high power circuit. The die pad 202 and the heat sink 208 are sized and shaped to receive the die 212. Typical die sizes may range from 4 mm×4 mm to 12 mm×12 mm. The die 212 may have a thickness ranging from about 6 mils to about 21 mils. The die 212 is attached to the heat sink 208 in a known manner, such as by a solder die attach process, which forms a layer of solder 214 between the heat sink 208 and the die 212, which allows heat to dissipate from the die 212 to the heat sink 208 by way of the solder 214 and then to the die pad 202 by way of the solder 210. In other embodiments, the die 212 may be attached to the heat sink 208 with an adhesive material layer or an adhesive tape.

The die 212 includes a plurality of die bonding pads 216. Ones of the die bonding pads 216 are electrically connected to corresponding ones of the lead fingers 204 by wires 218, preferably with a wire bonding process. For a power circuit, the wires 218 are relatively thick wires, such as about 10 mils in diameter, and are formed of a conductive material like aluminum. The wires 218 are connected to the bonding pads 216 and lead fingers 204 with a wire bonding process, for example, a wedge bonding process.

The die 212 also may include bonding pads 216 that are not located near a perimeter of the die 212, which can make it difficult to connect such bonding pads to the lead fingers. Accordingly, short wires 220 are used to connect some of the centrally located bonding pads to perimeter bonding pads, and from a perimeter bonding pad to a lead finger. Such wires 218 and 220 and wire bonding processes are known by those of skill in the art.

As previously discussed, in one embodiment the semiconductor device 200 includes a second die pad 206. In such embodiment, a second semiconductor integrated circuit die, such as a control circuit 222, is attached to the second die pad 206. In the embodiment shown, the control circuit 222 is not a high power circuit and does not generate excessive heat such that a heat sink is necessary. Thus, the control circuit 222 is directly attached to the die pad 206 with a die attach adhesive, such as an adhesive tape 224. Like the die 212, the control circuit 222 includes die bonding pads 216. The die bonding pads 216 are electrically connected to corresponding ones of the lead fingers 204 with wires 225. In one embodiment, the power die 212 also has one or more connections 226 to the control circuit 222. In one embodiment, the wires 225 and connections 226 are comprise relatively thin wires, such as gold wire having a diameter of about 1 to 2 mils, and are attached using a ball bonding process. However, various known wires of varying materials and diameters may be used, including both coated (insulated) and non-coated wires.

The semiconductor device 200 further includes an encapsulant 228 that covers a top surface of the integrated circuit die 212, the wires 218, 220, 225 and 226, the control die 222, and a top surface of the lead fingers 204, leaving at least bottom surfaces of the lead fingers 204 and the first and second die pads 20 and 206 exposed. The exposed portions of the lead fingers 204 are used to connect the device 200 to other devices, such as via a PCB and exposed bottom surface of the first die pad 202 allows heat to dissipate therefrom. The encapsulant 228 comprises a plastic as is commonly used in packaged electronic devices and is formed over the leadframe portions 202, 204 and 206, the die 212 and 222, and wires 218, 220, 225 and 226 with a molding process. The total thickness of an exemplary embodiment of the device 200 is about 2 mm.

Referring now to FIG. 3, a flow chart of a process for forming a packaged semiconductor device having an internal heat sink is shown. At step 300, a lead frame is provided. The lead frame has a plurality of inwardly extending lead fingers surrounding a die pad. The lead fingers may be formed in one or more rows that surround the die pad. The lead frame also may have more than one die pad, as shown in FIG. 2. Further, the lead frame is a single gauge type lead frame, meaning the one or more die pads and the lead fingers have substantially the same thickness. As previously discussed, the lead frame is formed of a conductive material, specifically electrically conductive for the lead fingers and thermally conductive for the die pad. In one embodiment of the invention, the lead frame is 8 mils thick and formed from a sheet of copper.

In a second step 302, a bottom surface or first surface of a heat spreader is attached to a top surface of the lead frame die pad. In one embodiment, the heat spreader is the same size and shape as the die pad, although the thickness of the heat spreader may differ from the thickness of the die pad. For example, if the die pad is rectangular and has a length L and a width W, then the heat spreader also is rectangular and has a length L and width W. If the lead frame includes a second die pad, then the second die pad may or may not include a second heat spreader, depending on the integrated circuit that will be attached to the second die pad (or second heat spreader). The heat spreader is formed of a thermally conductive material and attached to the die pad with a thermally conductive material. In an exemplary embodiment of the present invention, one of two die pads includes a heat spreader that is formed of NiPd plated copper and attached to the die pad with a high temperature solder.

In a third step 304, an integrated circuit (IC) is attached to a second or top surface of the heat spreader. The integrated circuit preferably is a high power circuit that generates heat during operation and benefits from a heat spreader to move heat away from the circuit. In one embodiment, the IC is attached to the heat spreader with a high temperature solder.

At step 306, a protective tape is attached to a bottom surface of the lead frame. The protective tape is used to prevent resin bleeding onto the lead frame during a subsequent molding operation, described below.

In one embodiment, a second IC, such as a control IC, is attached to first or top surface of a second die pad, as indicated at step 308. An example of the control IC is the control circuit 222 shown in FIG. 2.

At step 310, a first wire bonding operation is performed. More particularly, a wedge bonding operation is performed to electrically connect bonding pads of the power IC to respective ones of the lead fingers of the lead frame (e.g., wires 218 in FIG. 2). Additionally, if there are any bonding pads to be connected to other bonding pads, as done by wires 220 shown in FIG. 2, then such connection are made at this time. The wedge bonding can be carried out using copper or aluminum wires, as is known by those of skill in the art.

At step 312, a second wire bonding operation is performed. In this second wire bonding operation, the second or control IC bonding pads are electrically connected to respective ones of the lead frame lead fingers. The second wire bonding operation is carried out using thinner wires, such as gold wires have a diameter of about 1-2 mils (e.g., wires 225 in FIG. 2). Ball bonding is typically performed to connect the control pad die pads and the lead fingers.

A molding operation is performed at step 314. In the molding step 314, a plastic mold compound is formed over the integrated circuits, the wires, and the side surfaces of the die pads and heat spreader. The bottom surfaces of the lead fingers and die pads, since they are covered by the tape applied in step 306, are not covered with the mold compound. At step 314, the tape is removed from the bottom of the lead frame and thus the bottom surfaces of the lead fingers and die pads are exposed.

A plurality of packages is formed substantially simultaneously, thus, a singulation step 316 is performed to separate the packages from each other. For a QFN type package, the singulation step causes the outer side surfaces of the lead fingers to be exposed.

The single gauge lead frame design of the present invention allows an inexpensive lead frame to be used for power devices that require a heat spreader for heat diffusion. Further, using a relatively thin lead frame allows for fine pitch designs. That is, providing thin or standard lead fingers allows for finer pitch and better dimension control. For sawn type QFN packages, the amount and thickness of copper or metal lead frame material affects the quality of the saw singulation process. Thus, using a relatively thin lead frame allows for easier sawing and longer saw blade life.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiments disclosed, but covers modifications within the spirit and scope of the present invention as defined by the appended claims.

1. A single gauge lead frame for a semiconductor device, the leadframe comprising:
a central die pad having a first thickness;
a plurality of lead fingers surrounding the die pad, the lead fingers having a thickness equal to the first thickness; and
a heat spreader having a second thickness, wherein a first surface of the heat spreader is attached to a first surface of the die pad, and wherein a semiconductor integrated circuit is attached to a second surface of the heat spreader.

2. The single gauge lead frame of claim 1, wherein the second thickness is greater than the first thickness.

3. The single gauge lead frame of claim 1, wherein the first thickness is about 8 mils.

4. The single gauge lead frame of claim 1, wherein the heat spreader is attached to the die pad with solder.

5. The single gauge lead frame of claim 1, wherein the die pad, the lead fingers and the heat spreader are formed of copper.

6. The single gauge lead frame of claim 1, wherein the heat spreader is plated with NiPd.

7. The single gauge lead frame of claim 1, wherein the heat spreader and the die pad have substantially the same dimensions.

8. A semiconductor device, comprising:
a die pad having a first thickness;
a plurality of lead fingers surrounding the die pad, wherein the lead fingers have a thickness equal to the first thickness;
a heat spreader having a second thickness attached to a first surface of the die pad;
an integrated circuit attached to a second surface of the heat spreader;
a plurality of wires that electrically connect respective ones of the plurality of lead fingers to respective bonding pads on the integrated circuit; and
a mold compound surrounding the integrated circuit, the plurality of wires, and a top surface of the lead fingers, wherein a second surface of the die pad is exposed.

9. The semiconductor device of claim 8, wherein a bottom surface of the lead fingers is exposed.

10. The semiconductor device of claim 8, wherein the die pad, the lead fingers and the heat sink are formed of copper.

11. The semiconductor device of claim 10, wherein the second thickness is equal to the first thickness.

12. The semiconductor device of claim 11, wherein the heat spreader is plated with NiPd.

13. The semiconductor device of claim 8, wherein the heat spreader is attached to the die pad with solder and the integrated circuit is attached to the heat spreader with solder.

14. A semiconductor device, comprising:
a first die pad having a first thickness;
a second die pad having the first thickness;
a plurality of lead fingers surrounding the first and second die pads, wherein the lead fingers have a thickness equal to the first thickness;
a heat spreader having a second thickness attached to a first surface of the first die pad;
a first integrated circuit attached to a second surface of the heat spreader;
a second integrated circuit attached to a first surface of the second die pad;
a plurality of wires that electrically connect respective ones of the plurality of lead fingers to respective bonding pads of the first and second integrated circuits; and
a mold compound surrounding the first and second integrated circuits, the plurality of wires, and a top surface of the lead fingers, wherein second surfaces of the first and second die pads are exposed.

15. The semiconductor device of claim 14, wherein the first integrated circuit includes a power transistor.

16. The semiconductor device of claim 15, wherein a bottom surface of the lead fingers is exposed.

17. The semiconductor device of claim 15, wherein the first and second die pads, the lead fingers and the heat sink are formed of copper.

18. The semiconductor device of claim 17, wherein the second thickness is equal to the first thickness.

19. The semiconductor device of claim 17, wherein the heat spreader is plated with NiPd.

20. The semiconductor device of claim 17, wherein first integrated circuit is attached to the heat spreader with solder and the heat spreader is attached to the first die pad with solder.
